(19) United States
(12) Patent Application Publication
(10) Pub. No.: US 2025/0285944 A1
(43) Pub. Date: Sep. 11, 2025

(54) SEMICONDUCTOR DEVICE AND METHOD FOR MANUFACTURING SEMICONDUCTOR DEVICE

(71) Applicant: Rohm Co., Ltd., Kyoto-shi (JP)

(72) Inventors: Yasuki TAKATA, Kyoto-shi (JP); Kengo KASHIWAGI, Kyoto-shi (JP); Kota ISE, Kyoto-shi (JP); Takuro NAKAHARA, Kyoto-shi (JP); Hiromasa KONO, Kyoto-shi (JP); Shougo SHIRAISHI, Kyoto-shi (JP)

(21) Appl. No.: 19/219,367

(22) Filed: May 27, 2025

Related U.S. Application Data
(63) Continuation of application No. PCT/JP2023/041629, filed on Nov. 20, 2023.

(30) Foreign Application Priority Data
Dec. 2, 2022 (JP) 2022-193474

(51) Int. Cl. H01L 23/495; H01L 21/48; H01L 23/00; H01L 23/24; H01L 23/31; H01L 23/367; H10D 80/20

(52) U.S. Cl. CPC H01L 23/49517; H01L 21/4825; H01L 23/24; H01L 23/3677; H01L 23/49513; H01L 23/49562; H01L 23/49586; H01L 24/83; H01L 23/3121; H01L 24/32; H01L 24/48; H01L 24/73; H01L 2224/32245; H01L 2224/48245; H01L 2224/73215; H01L 2224/73265; H01L 2224/83048; H01L 2224/83205; H01L 2224/83224; H01L 2924/1815; H10D 80/251

(57) ABSTRACT

A semiconductor device includes a first lead, a semiconductor element, a second lead, a conductive member, and a sealing resin. The first lead includes a die pad having a die-pad obverse surface facing a first side in a thickness direction. The semiconductor element has an element obverse surface facing the first side in the thickness direction and includes a first electrode disposed on the element obverse surface. The semiconductor element is mounted on the die-pad obverse surface. The second lead has a second obverse surface facing the first side in the thickness direction and is spaced apart from the first lead in a first direction perpendicular to the thickness direction. The conductive member is electrically bonded to the first electrode and the second obverse surface. The sealing resin covers the semiconductor element. The conductive member is in direct contact with the second lead.

### TECHNICAL FIELD

The present disclosure relates to a semiconductor device and a method for manufacturing a semiconductor device.

### BACKGROUND ART

Semiconductor devices incorporating semiconductor elements are provided in various configurations. JP-A-2021-158180 discloses an example of a conventional semiconductor device. The semiconductor device disclosed in JP-A-2021-158180 includes a semiconductor element, a conductive plate, a drive pad, a conductive member, and a sealing resin. The semiconductor element is mounted on the conductive obverse surface of the conductive plate. The conductive member connects an obverse-surface drive electrode, which is disposed on the element obverse surface of the semiconductor element, and the drive pad. The sealing resin seals a portion of the conductive plate, a portion of the drive pad, the semiconductor element, and the conductive member.

The semiconductor element is bonded to the conductive obverse surface via a conductive bonding material, such as solder. The conductive member is bonded to the obverse-surface drive electrode via a conductive bonding material, such as solder. That is, two layers of a conductive bonding material are present between the conductive obverse surface and the conductive member. The shape of the layers of a conductive bonding material is not consistent, resulting in inconsistencies in the height of the conductive member from the conductive obverse surface (the position of the conductive plate in the thickness direction).

### BRIEF DESCRIPTION OF THE DRAWINGS

FIG. 1 is a plan view of a semiconductor device according to a first embodiment of the present disclosure.

FIG. 2 is a bottom view of the semiconductor device shown in FIG. 1.

FIG. 3 is a plan view of the semiconductor device shown in FIG. 1 (with the sealing resin shown as transparent).

FIG. 4 is a right-side view of the semiconductor device shown in FIG. 1.

FIG. 5 is a left-side view of the semiconductor device shown in FIG. 1.

FIG. 6 is a sectional view taken along line VI-VI in FIG. 3.

FIG. 7 is a sectional view taken along line VII-VII in FIG. 3.

FIG. 8 is a sectional view taken along line VIII-VIII in FIG. 3.

FIG. 9 is a partially enlarged view of FIG. 6.

FIG. 10 is a sectional view for illustrating a step of an example method for manufacturing a semiconductor device shown in FIG. 1.

FIG. 11 is a sectional view for illustrating a step of the example method for manufacturing a semiconductor device shown in FIG. 1.

FIG. 12 is a sectional view for illustrating a step of the example method for manufacturing a semiconductor device shown in FIG. 1.

FIG. 13 is an enlarged sectional view of a semiconductor device according to a first variation of the first embodiment.

FIG. 14 is an enlarged sectional view of a semiconductor device according to a second embodiment of the present disclosure.

FIG. 15 is a sectional view of a semiconductor device according to a third embodiment of the present disclosure.

FIG. 16 is a sectional view of a semiconductor device according to a fourth embodiment of the present disclosure.

FIG. 17 is a sectional view of a semiconductor device according to a fifth embodiment of the present disclosure.

FIG. 18 is a sectional view for illustrating a step of an example method for manufacturing a semiconductor device shown in FIG. 17.

FIG. 19 is a sectional view for illustrating a step of the example method for manufacturing a semiconductor device shown in FIG. 17.

FIG. 20 is a sectional view for illustrating a step of the example method for manufacturing a semiconductor device shown in FIG. 17.

FIG. 21 is a sectional view for illustrating a step of the example method for manufacturing a semiconductor device shown in FIG. 17.

FIG. 22 is a sectional view of a semiconductor device according to a first variation of the fifth embodiment.

FIG. 23 is an enlarged sectional view of a semiconductor device according to a second variation of the fifth embodiment.

FIG. 24 is a sectional view for illustrating a step of an example method for manufacturing a semiconductor device shown in FIG. 23.

FIG. 25 is a sectional view for illustrating a step of the example method for manufacturing a semiconductor device shown in FIG. 23.

FIG. 26 is a sectional view for illustrating a step of the example method for manufacturing a semiconductor device shown in FIG. 23.

### DETAILED DESCRIPTION OF EMBODIMENTS

The following specifically describes preferred embodiments of the present disclosure with reference to the drawings.

In the present disclosure, the terms such as “first”, “second”, “third”, and so on are used only as labels and not to imply an order of the items referred to by the terms.

In the description of the present disclosure, the expression “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expressions “An object A is arranged in an object B”, and “An object A is arranged on an object B” imply the situation where, unless otherwise specifically noted, “the object A is arranged directly in or on the object B”, and “the object A is arranged in or on the object B, with something else interposed between the object A and the object B”. Further, the expression “An object A is located on an object B” implies the situation where, unless otherwise specifically noted, “the object A is located on the object B, in contact with the object B”, and “the object A is located on the object B, with something else interposed between the object A and the object B”. Still further, the expression “An object A overlaps with an object B as viewed in a certain direction” implies the situation where, unless otherwise specifically noted, “the object A overlaps with the entirety of the object B”, and “the object A overlaps with a part of the object B”.

### First Embodiment

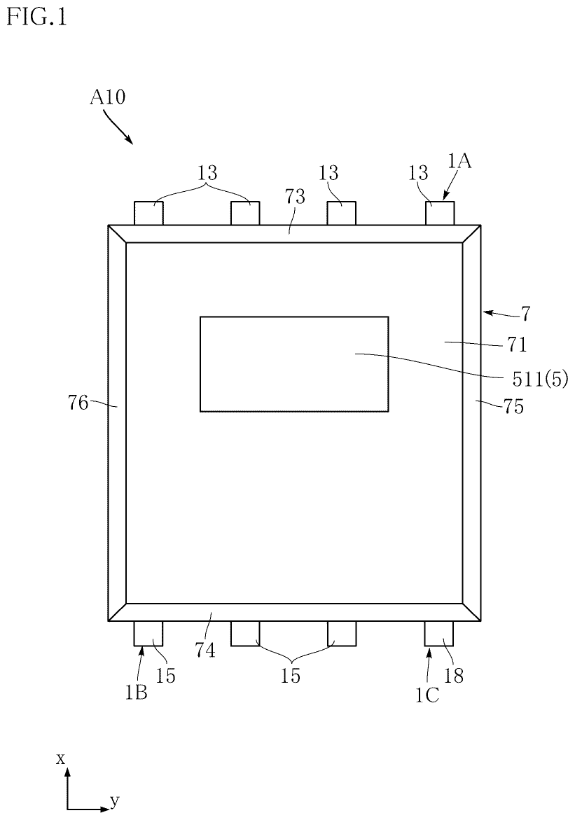

With reference to FIGS. 1 to 9, the following describes a semiconductor device A10 according to a first embodiment of the present disclosure. The semiconductor device A10 includes a plurality of leads 1A, 1B, and 1C, a semiconductor element 2, an insulating part 3, a metal laminate 4, a conductive member 5, conductive bonding materials 61 and 62, and a sealing resin 7.

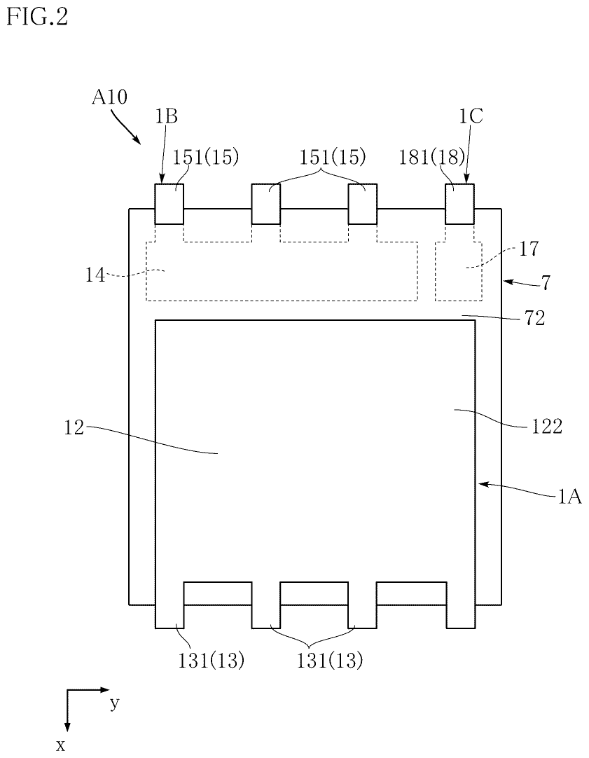

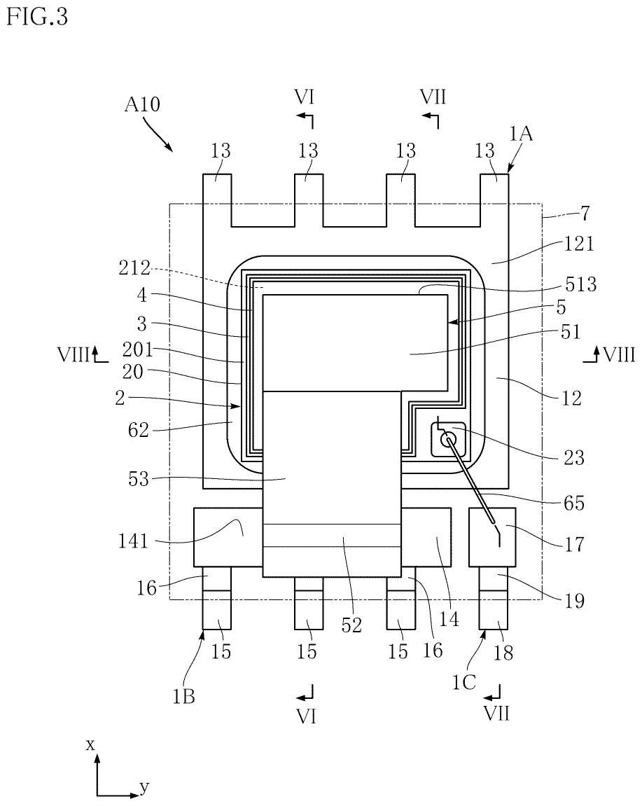

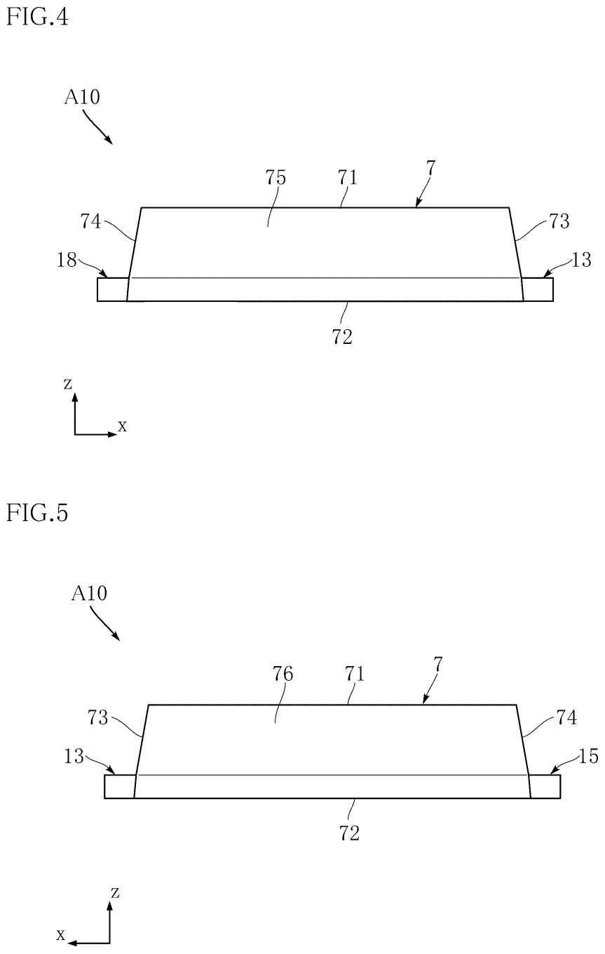

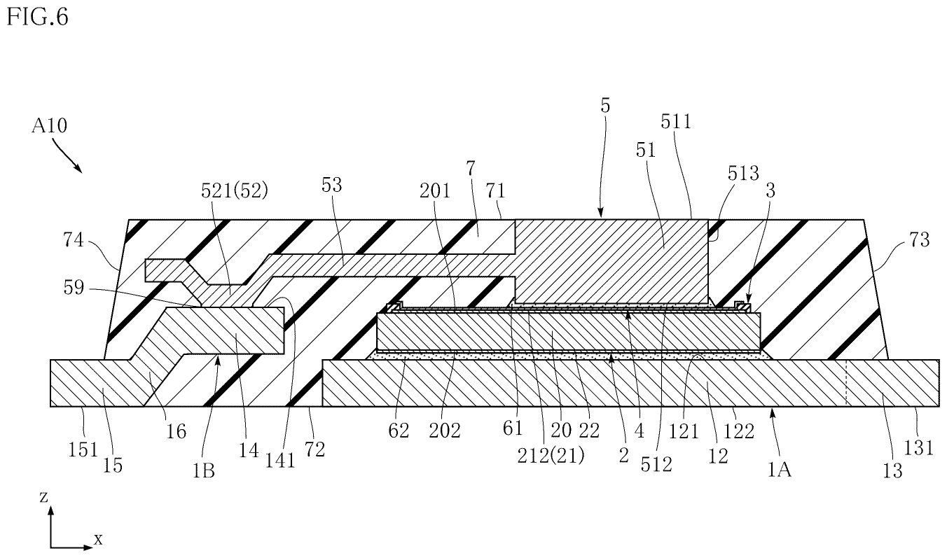

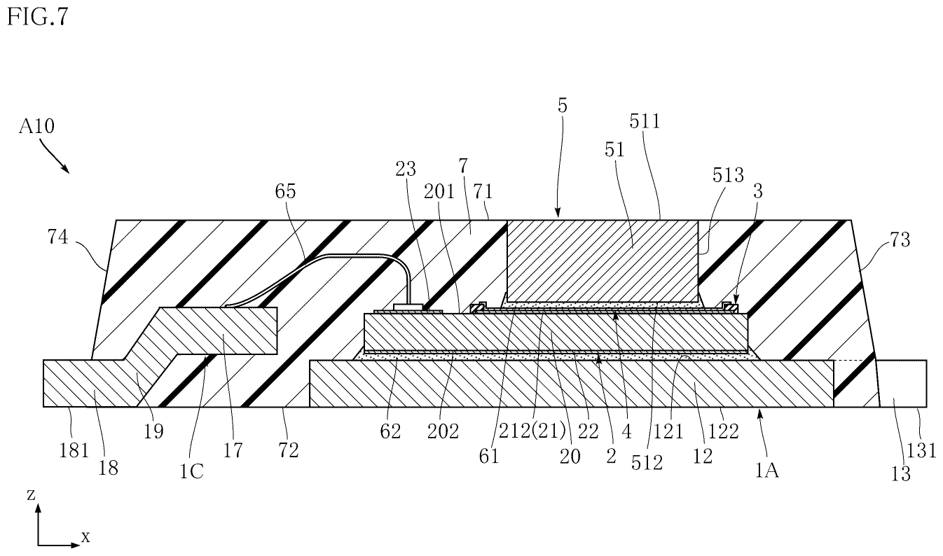

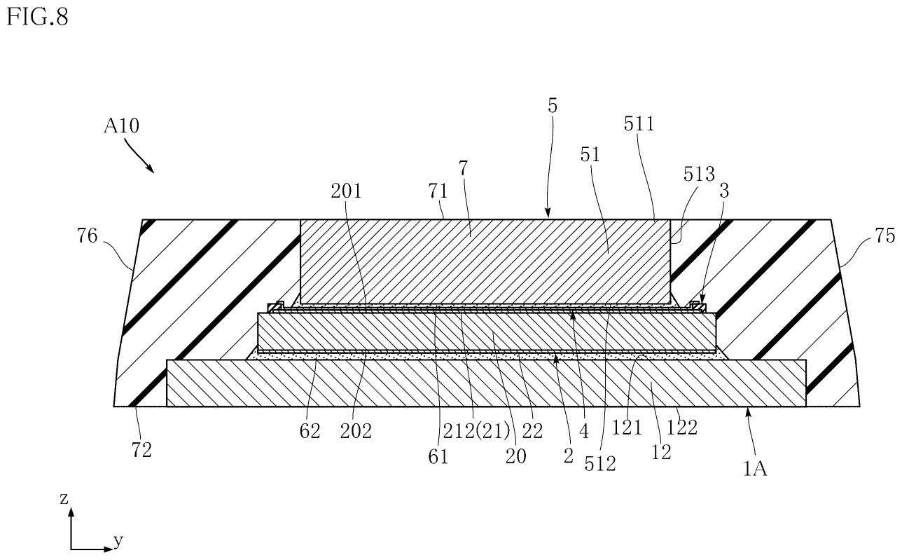

FIG. 1 is a plan view of the semiconductor device A10. FIG. 2 is a bottom view of the semiconductor device A10. FIG. 3 is a plan view of the semiconductor device A10. FIG. 4 is a right-side view of the semiconductor device A10. FIG. 5 is a left-side view of the semiconductor device A10. FIG. 6 is a sectional view taken along line VI-VI in FIG. 3. FIG. 7 is a sectional view taken along line VII-VII in FIG. 3. FIG. 8 is a sectional view taken along line VIII-VIII in FIG. 3. For convenience of description, FIG. 3 shows the sealing resin 7 as transparent.

In the description of the semiconductor device A10, the thickness direction of the semiconductor element 2 is referred to as “thickness direction z”. A direction perpendicular to the thickness direction z is referred to as “first direction x”. The direction perpendicular to both the thickness direction z and the first direction x is referred to as “second direction y”. As shown in FIGS. 1 and 2, the semiconductor device A10 is substantially rectangular as viewed in the thickness direction z. The size of the semiconductor device A10 is not specifically limited.

The leads 1A, 1B, and 1C are formed from a metal plate (a lead frame) through punching, bending, and other processes. The constituent material of the leads 1A, 1B, and 1C is not specifically limited, and examples of the constituent material include copper (Cu), nickel (Ni), and alloys of these metals. In the present embodiment, the constituent material of the leads 1A, 1B, and 1C is Cu. The thickness of the leads 1A, 1B, and 1C may be, but not limited to, 0.1 to 0.3 mm, for example.

As shown in FIG. 3, the lead 1A is located on a first side in the first direction x from the leads 1B and 1C. The leads 1B and 1C are arranged next to each other in the second direction y. As viewed in the thickness direction z, the leads 1A to 1C are spaced apart from each other. In terms of the size as viewed in the thickness direction z, the lead 1A is the largest, and the lead 1C is the smallest.

As shown in FIG. 3 and FIGS. 6 to 8, the lead 1A includes a die pad 12 and a plurality of (four in the present embodiment) first terminal portions 13. For example, the die pad 12 is rectangular as viewed in the thickness direction z. The die pad 12 has an obverse surface 121 and a reverse surface 122. The obverse surface 121 faces a first side in the thickness direction z, and the reverse surface 122 faces away from the obverse surface 121 (faces a second side in the thickness direction z). The obverse surface 121 is where the semiconductor element 2 is mounted. As shown in, for example, FIGS. 2 and 6, the reverse surface 122 is exposed from the sealing resin 7. When the semiconductor device A10 is mounted on a circuit board that is not shown in the figures, the reverse surface 122 is joined to the circuit board using a bonding material, such as solder.

The first terminal portions 13 are located on the first side in the first direction x from the die pad 12 (the right side in FIG. 6). Each first terminal portion 13 is connected to the end of the die pad 12 on the first side in the first direction x and extends toward the first side in the first direction x. The first terminal portions 13 are arranged at intervals in the second direction y. Each first terminal portion 13 includes a reverse-surface mounting portion 131. The reverse-surface mounting portion 131 faces the second side in the thickness direction z (the bottom side in FIG. 6). The reverse-surface mounting portion 131 is exposed from the sealing resin 7. When the semiconductor device A10 is mounted on a circuit board that is not shown in the figures, the reverse-surface mounting portion 131 is joined to the circuit board using a bonding material, such as solder.

As shown in FIGS. 3 and 6, the lead 1B includes a pad portion 14, a plurality of (three in the present embodiment) second terminal portions 15, and a plurality of (three in the present embodiment) bent portions 16. The pad portion 14 is located on the first side in the thickness direction z (the upper side in FIG. 6) from the second terminal portions 15. In the first direction x, the pad portion 14 is located inward from the second terminal portions 15 and is covered with the sealing resin 7. The pad portion 14 has an obverse surface 141 facing the first side in the thickness direction z.

The second terminal portions 15 are located on the second side in the first direction x from the die pad 12 of the lead 1A (the left side in FIG. 6). Each second terminal portion 15 extends toward the second side in the first direction x. The second terminal portions 15 are arranged at intervals in the second direction y. Each second terminal portion 15 includes a reverse-surface mounting portion 151. The reverse-surface mounting portion 151 faces the second side in the thickness direction z (the bottom side in FIG. 6). The reverse-surface mounting portion 151 is exposed from the sealing resin 7. When the semiconductor device A10 is mounted on a circuit board that is not shown in the figures, the reverse-surface mounting portion 151 is joined to the circuit board using a bonding material, such as solder. Each bent portion 16 connects the pad portion 14 and a corresponding second terminal portion 15 and is bent as viewed in the second direction y.

As shown in FIGS. 3 and 7, the lead 1C includes a pad portion 17, a second terminal portion 18, and a bent portion 19. The pad portion 17 is located on the first side in the thickness direction z (the upper side in FIG. 7) from the second terminal portion 18. In the first direction x, the pad portion 17 is located inward from the second terminal portion 18 and is covered with the sealing resin 7.

The second terminal portion 18 is located on the second side in the first direction x (the left side in FIG. 7) from the die pad 12 of the lead 1A. The second terminal portion 18 extends toward the second side in the first direction x. The second terminal portions 15 of the lead 1B and the second terminal portion 18 of the lead 1C are arranged at intervals in the second direction y. The second terminal portion 18 has a reverse-surface mounting portion 181. The reverse-surface mounting portion 181 faces the second side in the thickness direction z (the bottom side in FIG. 7). The reverse-surface mounting portion 181 is exposed from the sealing resin 7. When the semiconductor device A10 is mounted on a circuit board that is not shown in the figures, the reverse-surface mounting portion 181 is joined to the circuit board using a bonding material, such as solder. The bent portion 19 connects the pad portion 17 and the second terminal portion 18 and is bent as viewed in the second direction y.

The semiconductor element 2 implements the electrical function of the semiconductor device A10. The type of the semiconductor element 2 is not specifically limited. In the present embodiment, the semiconductor element 2 is configured as a transistor. The semiconductor element 2 is mounted on the obverse surface 121 of the die pad 12. As shown in FIGS. 3 and 6 to 8, the semiconductor element 2 includes an element body 20, a first electrode 21, a second electrode 22, and a third electrode 23.

The element body 20 is rectangular as viewed in the thickness direction z. The element body 20 has an element obverse surface 201 and an element reverse surface 202. The element obverse surface 201 and the element reverse surface 202 face away from each other in the thickness direction z. The element obverse surface 201 faces the same side as the obverse surface 121 of the die pad 12 in the thickness direction z (the first side in the thickness direction z). Thus, the element reverse surface 202 faces the obverse surface 121.

The first electrode 21 and the third electrode 23 are disposed on the element obverse surface 201. The second electrode 22 is disposed on the element reverse surface 202. The constituent materials of first electrode 21, the second electrode 22, and the third electrode 23 include copper, aluminum (Al), and alloys of these metals. In the present embodiment, the first electrode 21 is the source electrode, the second electrode 22 is the drain electrode, and the third electrode 23 is the gate electrode.

In the present embodiment, the first electrode 21 covers most of the element obverse surface 201. Specifically, the first electrode 21 covers the element obverse surface 201, which is rectangular, except for its periphery and one corner (the lower right corner in FIG. 3). The first electrode 21 includes a first-electrode pad portion 212. As viewed in the thickness direction z, the first-electrode pad portion 212 is located inside the insulating part 3. The third electrode 23 is located at one corner of the element obverse surface 201 (the lower right corner in FIG. 3). The second electrode 22 covers the entire (or substantially entire) element reverse surface 202.

The second electrode 22 is bonded to the obverse surface 121 of the die pad 12 via a conductive bonding material 62. The conductive bonding material 62 electrically connects the die pad 12 and the second electrode 22. The conductive bonding material 62 is solder, for example.

The semiconductor device A10 includes a wire 65. The wire 65 is electrically bonded to the third electrode 23 and the pad portion 17 of the lead 1C. The wire 65 electrically connects the third electrode 23 and the lead 1C.

As shown in FIGS. 3 and 6 to 8, the insulating part 3 is arranged to extend across the first electrode 21 and the element obverse surface 201. As viewed in the thickness direction z, the insulating part 3 has an annular shape that overlaps with the outer edge of the first electrode 21. The outer edge of the insulating part 3 is located closely along to the outer edge of the element obverse surface 201 as viewed in the thickness direction z. As viewed in the thickness direction z, the region of the first electrode 21 located inside the inner edge of the insulating part 3 is the first-electrode pad portion 212. In one example, the insulating part 3 is composed of a plurality of insulating layers stacked on top of each other. The insulating part 3 may include a lower insulating layer made of nitride, and an upper insulating layer made of a resin material, for example. Examples of nitride forming the lower insulating layer include SiN, SiON, and SiO₂. Examples of the resin material forming the upper insulating layer include a polyimide resin.

As shown in FIGS. 3 and 6 to 8, the metal laminate 4 is arranged to extend across the first electrode 21 and the insulating part 3 and is composed of a plurality of metal layers that are stacked on top of each other, for example. The metal laminate 4 may include a metal layer containing titanium (Ti), a metal layer containing nickel, and a metal layer containing silver (Ag), and they are stacked in the stated order. Unlike the present embodiment, the semiconductor device of the present disclosure may not include the insulating part 3 and the metal laminate 4.

As shown in FIGS. 3 and 6, the conductive member 5 is electrically bonded to the first electrode 21 of the semiconductor element 2 and the lead 1B. The conductive member 5 is made of a metal plate having varying thicknesses (having multi-gauge strips). The metal may be copper (Cu) or a copper alloy. In the present embodiment, the constituent material of the conductive member 5 is the same as that of the lead 1B, namely Cu. The conductive member 5 is a metal plate having been processed by bending and punching. In the present embodiment, the conductive member 5 includes an element bonding portion 51, a lead bonding portion 52, and an intermediate portion 53. The element bonding portion 51 is a portion with a greater thickness (the dimension in the thickness direction z) among the multi-gauge strips and has a rectangular shape that is elongated in the second direction y as viewed in the thickness direction z. The element bonding portion 51 is electrically bonded to the first-electrode pad portion 212 of the first electrode 21 via the conductive bonding material 61. The conductive bonding material 61 electrically connects the element bonding portion 51 (the conductive member 5) and the first-electrode pad portion 212. The conductive bonding material 61 is solder, for example.

The element bonding portion 51 has an obverse surface 511, a reverse surface 512, and an end surface 513. The obverse surface 511 and the reverse surface 512 face away from each other in the thickness direction z. The obverse surface 511 faces the same side as the obverse surface 121 of the die pad 12 in the thickness direction z (the first side in the thickness direction z). As shown in FIGS. 1 and 6 to 8, the obverse surface 511 is exposed from the sealing resin 7. The reverse surface 512 faces the same side as the reverse surface 122 of the die pad 12 in the thickness direction z (the second side in the thickness direction z). As shown in FIGS. 6 to 8, the reverse surface 512 is bonded to the first-electrode pad portion 212 of the semiconductor element 2. This allows the conductive member 5 to dissipate heat generated by the semiconductor element 2 through its obverse surface 511. The end surface 513 is connected to the obverse surface 511 and the reverse surface 512 and is located between the obverse surface 511 and the reverse surface 512 in the thickness direction z. The end surface 513 faces the first side in the first direction x. The shape of the element bonding portion 51 is not specifically limited.

The lead bonding portion 52 is electrically bonded to the pad portion 14 of the lead 1B. The lead bonding portion 52 is bonded in direct contact with the obverse surface 141 of the pad portion 14. In the present embodiment, the lead bonding portion 52 is joined to the obverse surface 141 of the pad portion 14 by ultrasonic bonding. As shown in FIG. 6, the lead bonding portion 52 is appropriately bent as viewed in the second direction y, forming a protruding portion 521 that is closer to the second side in the thickness direction z (lower side in the figure) than the rest. A solid-state bonding interface 59 is present between the protruding portion 521 and the pad portion 14. The solid-state bonding interface 59 forms when the protruding portion 521 and the pad portion 14 are joined together in the solid state using ultrasonic vibrations and pressure applied during ultrasonic bonding process. Alternatively, other solid-state bonding methods, including diffusion bonding and thermal compression bonding, may be used to join the lead bonding portion 52 to the obverse surface 141 of the pad portion 14.

The intermediate portion 53 is present between the element bonding portion 51 and the lead bonding portion 52 in the first direction x. The intermediate portion 53 is connected to both the element bonding portion 51 and the lead bonding portion 52.

The sealing resin 7 covers the semiconductor element 2, the insulating part 3, and the metal laminate 4, as well as a portion of each of the conductive member 5 and the leads 1A, 1B, and 1C. The sealing resin 7 is made of a black epoxy resin, for example.

As shown in FIGS. 1, 2, and 4 to 8, the sealing resin 7 has a resin obverse surface 71, a resin reverse surface 72, and resin side surfaces 73 to 76. The resin obverse surface 71 and the resin reverse surface 72 face away from each other in the thickness direction z. The resin obverse surface 71 faces the first side in the thickness direction z, similarly to the obverse surface 121 of the element obverse surface 201. As shown in FIG. 1, the resin obverse surface 71 exposes the obverse surface 511 of the element bonding portion 51 of the conductive member 5. The resin reverse surface 72 faces the second side in the thickness direction z, similarly to the element reverse surface 202 and the reverse surface 122. As shown in FIG. 2, the resin reverse surface 72 exposes the reverse surface 122 of the die pad 12, the reverse-surface mounting portions 131 of the first terminal portions 13, the reverse-surface mounting portions 151 of the second terminal portions 15, and the reverse-surface mounting portion 181 of the second terminal portion 18.

The resin side surfaces 73 to 76 are each connected to the resin obverse surface 71 and the resin reverse surface 72, and each located between the resin obverse surface 71 and the resin reverse surface 72 in the thickness direction z. The resin side surfaces 73 and 74 face away from each other in the first direction x. The resin side surface 73 faces the first side in the first direction x, and the resin side surface 74 faces the second side in the first direction x. The resin side surfaces 75 and 76 face away from each other in the second direction y. The resin side surface 75 faces a first side in the second direction y, and the resin side surface 76 faces a second side in the second direction y. As shown in FIG. 1, a portion of each first terminal portion 13 protrudes from the resin side surface 73. Also, a portion of each second terminal portion 15 and a portion of the second terminal portion 18 protrude from the resin side surface 74. In the illustrated example, the resin side surfaces 73 to 76 are each slightly inclined relative to the thickness direction z. Note that the shape of the sealing resin 7 shown in FIGS. 1, 2, and 4 to 8 is only one example. The shape of the sealing resin 7 is not limited to this example.

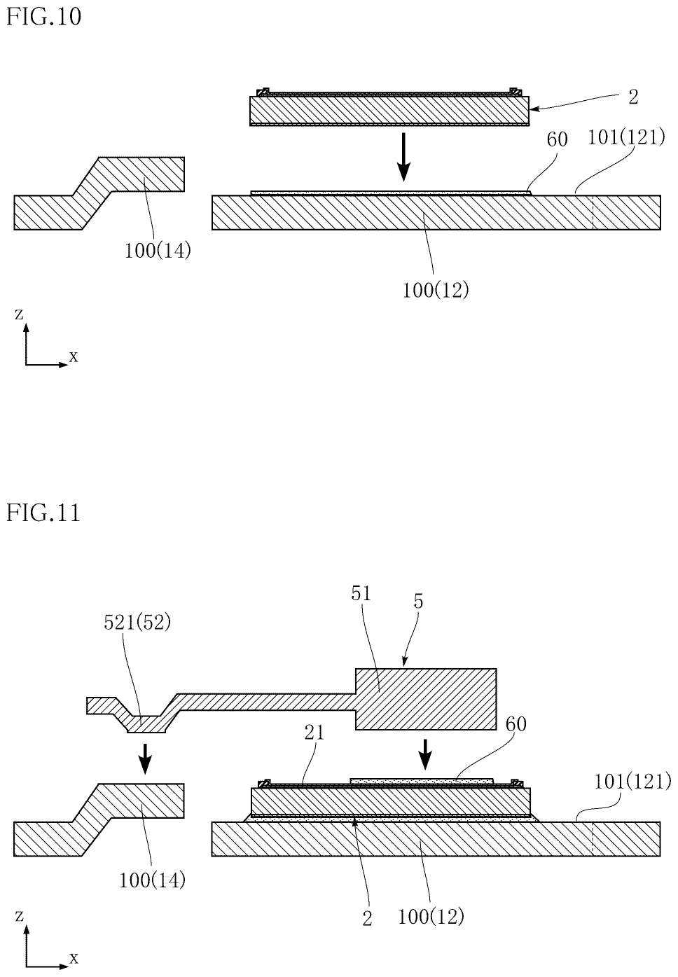

The following describes a method for manufacturing a semiconductor device A10, with reference to FIGS. 10 to 12. FIGS. 10 to 12 are sectional views corresponding to FIG. 6, each illustrating a step of the method for manufacturing a semiconductor device A10.

First, a lead frame 100 and a semiconductor element 2 are prepared as shown in FIG. 10. The lead frame 100 is a plate from which the leads 1A, 1B, and 1C will be formed. The lead frame 100 is formed from a metal plate through punching, bending, and other processes. The process for forming the lead frame 100 is not specifically limited. The description of the process for manufacturing the semiconductor element 2 is omitted. In a separate step, a conductive member 5 is prepared. The conductive member 5 is formed from a metal plate having multi-gauge strips through punching, bending, and other processes. The process for forming the conductive member 5 is not specifically limited.

Subsequently, as shown in FIG. 10, a solder paste 60 is applied to the obverse surface 101 of the lead frame 100 to cover the portion for forming the obverse surface 121 of the die pad 12. Then, the semiconductor element 2 is placed on the applied solder paste 60.

Subsequently, as shown in FIG. 11, the solder paste 60 is applied to the first electrode 21 of the semiconductor element 2. Then, as shown in FIG. 11, the conductive member 5 is placed to span across the semiconductor element 2 and the portion of the lead frame 100 that is for forming the pad portion 14. In this state, the element bonding portion 51 is placed on the solder paste 60, whereas the protruding portion 521 of the lead bonding portion 52 is placed directly on the portion of the lead frame 100 that is for forming the pad portion 14.

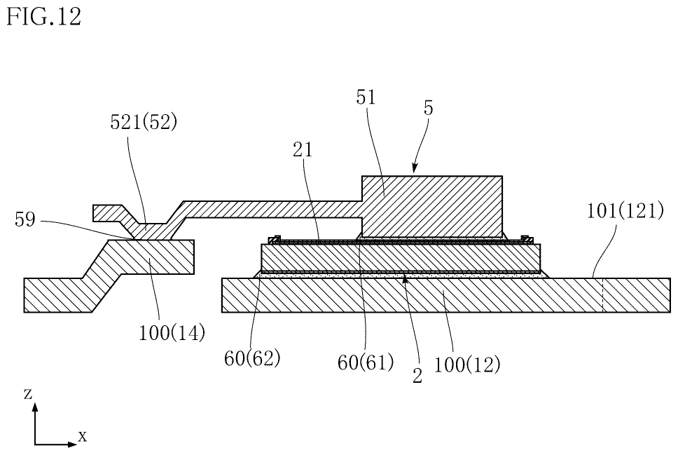

Subsequently, the protruding portion 521 of the lead bonding portion 52 is joined by ultrasonic bonding to the portion of the lead frame 100 that is for forming the pad portion 14. Specifically, the protruding portion 521 is placed into direct contact with the portion for forming the pad portion 14 and pressed against it. In this state, ultrasonic vibrations are applied to create a solid-state bond. As a result, a solid-state bonding interface 59 forms between the protruding portion 521 and the portion for forming the pad portion 14 as shown in FIG. 12.

Subsequently, a reflow process is performed. The reflow process involves melting the solder paste 60 and subsequent cooling, allowing the molten solder to solidify. This forms a conductive bonding material 62, bonding the semiconductor element 2 to the portion of the lead frame 100 that is for forming the die pad 12. This also forms a conductive bonding material 61, bonding the element bonding portion 51 of the conductive member 5 to the first electrode 21.

Subsequently, a wire 65 is bonded using wire bonding. Then, a sealing resin 7 is formed by molding so as to cover the semiconductor element 2, the insulating part 3, and the metal laminate 4, as well as a portion of each of the conductive member 5 and the lead frame 100. Subsequently, the lead frame 100 is appropriately cut, separating the leads 1A, 1B and 1C from each other. Through the steps described above, the semiconductor device A10 as shown in FIGS. 1 to 9 is manufactured.

The following describes operation of the present embodiment.

According to the present embodiment, the lead bonding portion 52 of the conductive member 5 is bonded in direct contact with the obverse surface 141 of the pad portion 14. That is, no bonding material or the like is interposed between the lead bonding portion 52 and the obverse surface 141, and the height (the position in the thickness direction z) of the conductive member 5 from the obverse surface 121 of the die pad 12 is determined by the height of the obverse surface 141 of the pad portion 14. The semiconductor device A10 thus ensures that the height of the conductive member 5 from the obverse surface 121 is controlled to be consistent, irrespective of the thicknesses (the dimensions in the thickness direction z) of the conductive bonding materials 61 and 62. By controlling the position of the conductive member 5 to an appropriate height, the sealing resin 7 is prevented from forming on the obverse surface 511 of the element bonding portion 51. In addition, the lead bonding portion 52 is joined to the pad portion 14 before the reflow process. This helps prevent the conductive member 5 from rotating around an axis extending in the thickness direction z when the solder paste 60 melts during the reflow process.

According to the present embodiment, in addition, the lead bonding portion 52 of the conductive member 5 is joined to the obverse surface 141 of the pad portion 14 by ultrasonic bonding. Thus, the lead bonding portion 52 and the pad portion 14 are bonded in direct contact, without any bonding material interposed between them.

According to the present embodiment, in addition, the conductive member 5 is made of the same constituent material as that of the lead 1B, namely Cu. This allows the lead bonding portion 52 and the pad portion 14 to be firmly bonded by ultrasonic bonding.

According to the present embodiment, in addition, the obverse surface 511 of the element bonding portion 51 of the conductive member 5 is exposed from the resin obverse surface 71. This allows the semiconductor device A10 to dissipate heat generated by the semiconductor element 2 through the obverse surface 511 of the conductive member 5. The reverse surface 122 of the die pad 12 is exposed from the resin reverse surface 72. This allows the semiconductor device A10 to dissipate heat generated by the semiconductor element 2 through the reverse surface 122 of the die pad 12. That is, the semiconductor device A10 is configured to dissipate heat from both sides in the thickness direction z, which is more efficient than dissipating heat from only one side in the thickness direction z.

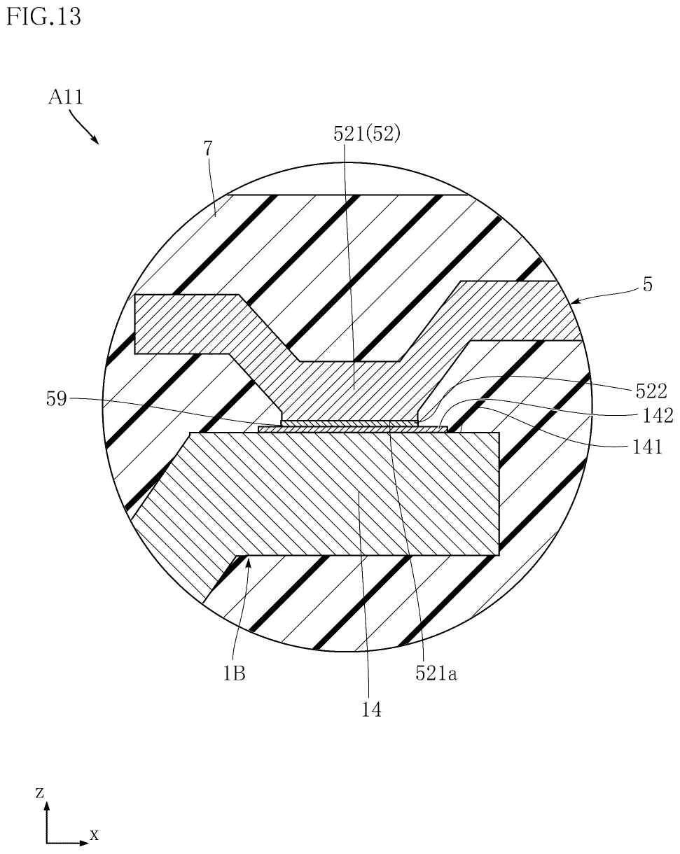

FIG. 13 shows a variation of the semiconductor device A10 according to the first embodiment. In the figure, elements that are identical or similar to those of the embodiment described above are indicated by the same reference numerals, and redundant descriptions are omitted.

### First Variation of First Embodiment:

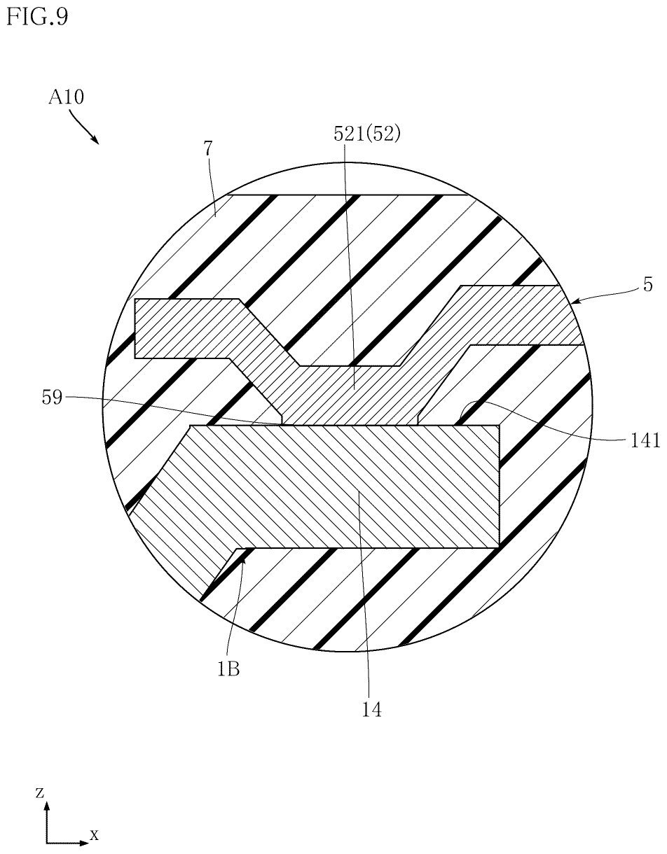

FIG. 13 is a semiconductor device A11 according to a first variation of the first embodiment. FIG. 13 is a partially enlarged sectional view of the semiconductor device A11 and corresponds to FIG. 9. The pad portion 14 of the lead 1B according to this variation includes a plating layer 142 on the obverse surface 141. The constituent material of the plating layer 142 is silver (Ag), for example, but not limited to this. In addition, the lead bonding portion 52 of the conductive member 5 according to this variation includes a plating layer 522 on a contact surface 521a of the protruding portion 521, facing the second side in the thickness direction z. The constituent material of the plating layer 522 is the same as that of the plating layer 142, which is silver (Ag) in this variation. When created by ultrasonic bonding, silver-to-silver bonds are stronger than silver-to-copper bonds. Hence, the semiconductor device A11 forms a stronger bond between the lead bonding portion 52 and the pad portion 14 than the semiconductor device A10.

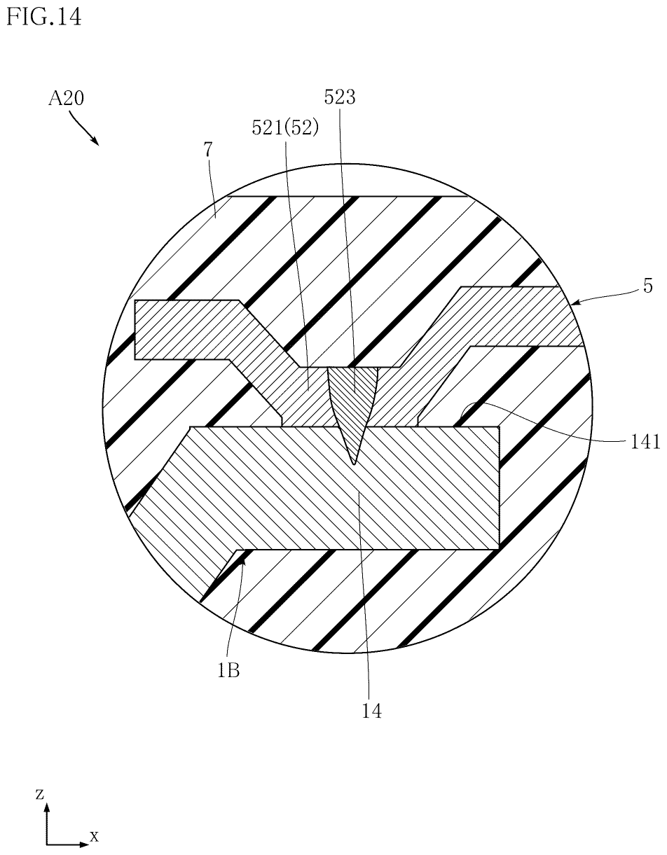

FIGS. 14 to 26 show other embodiments of the present disclosure. In these figures, elements that are identical or similar to those of the embodiment described above are indicated by the same reference numerals.

### Second Embodiment

FIG. 14 is a view for illustrating a semiconductor device A20 according to a second embodiment of the present disclosure. FIG. 14 is an enlarged sectional view of the semiconductor device A20 and corresponds to FIG. 9. The semiconductor device A20 of the present embodiment differs from the first embodiment in the process used for bonding the lead bonding portion 52 of the conductive member 5 and the pad portion 14 of the lead 1B. Other than that, the configurations and operation of the present embodiment are similar to those of the first embodiment. Note that the present embodiment may be combined with any part of the first embodiment and the variations described above.

For the semiconductor device A20 of the present embodiment, the lead bonding portion 52 of the conductive member 5 and the pad portion 14 of the lead 1B are joined by laser welding using a laser beam. The lead bonding portion 52 has a welding mark 523 that extends to the interior of the pad portion 14. The welding mark 523 forms when a portion of the lead bonding portion 52 and a portion of the pad portion 14 are fused and joined together during laser welding. Note that the lead bonding portion 52 may have a plurality of welding marks 523.

According to the present embodiment, the lead bonding portion 52 of the conductive member 5 is bonded in direct contact with the obverse surface 141 of the pad portion 14. Thus, similarly to the semiconductor device A10, the semiconductor device A20 ensures that the height of the conductive member 5 from the obverse surface 121 of the die pad 12 is controlled to be consistent. According to the present embodiment, in addition, the lead bonding portion 52 of the conductive member 5 is joined to the obverse surface 141 of the pad portion 14 by laser welding. Thus, the lead bonding portion 52 and the pad portion 14 are bonded in direct contact, without any bonding material interposed between them. In addition, the semiconductor device A20 has a configuration in common with the semiconductor device A10, thereby achieving the same effect as the semiconductor device A10.

As can be understood from the first and second embodiments, the process for joining the lead bonding portion 52 of the conductive member 5 and the pad portion 14 of the lead 1B is not specifically limited. It is sufficient that the lead bonding portion 52 and the pad portion 14 are bonded in direct contact with each other.

### Third Embodiment

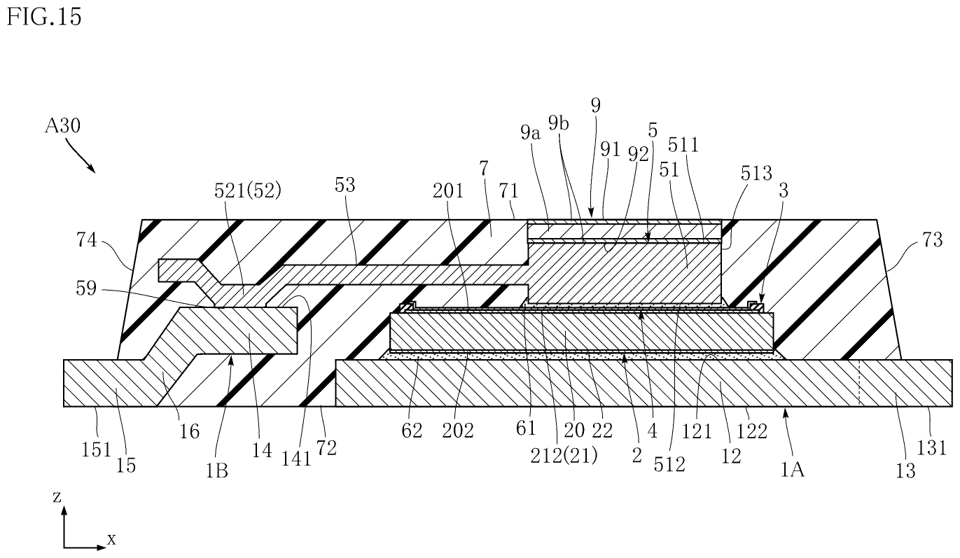

FIG. 15 is a view for illustrating a semiconductor device A30 according to a third embodiment of the present disclosure. FIG. 15 is a sectional view of the semiconductor device A30 and corresponds to FIG. 6. The semiconductor device A30 of the present embodiment differs from the first embodiment in the addition of a heat-conducting member 9 that is exposed from the resin obverse surface 71 of the sealing resin 7. Other than that, the configurations and operation of the present embodiment are similar to those of the first embodiment. Note that the present embodiment may be combined with any part of the first and second embodiments and the variations described above.

The semiconductor device A30 of the present embodiment additionally includes the heat-conducting member 9. The heat-conducting member 9 includes an insulating plate 9a and two metal layers 9b. The insulating plate 9a is a plate having, for example, a rectangular shape as viewed in the thickness direction z. The insulating plate 9a is made of a ceramic material with excellent thermal conductivity, which is aluminum nitride (AlN) in the present embodiment. The shape and the constituent material of the insulating plate 9a are not specifically limited. The two metal layers 9b are formed on the opposite surfaces of the heat-conducting member 9 in the thickness direction z. Each metal layer 9b is identical in shape and size to the insulating plate 9a as viewed in the thickness direction z. The constituent material of each metal layer 9b is not specifically limited, and examples of the constituent material include copper (Cu), silver (Ag), gold (Au), and alloys of these metals. In the present embodiment, the metal layers 9b are made of copper (Cu). In the present embodiment, the heat-conducting member 9 is a direct bonded copper (DBC) substrate. A DBC substrate is a ceramic substrate with silver foil bonded to both sides.

The heat-conducting member 9 has an obverse surface 91 and a reverse surface 92. The obverse surface 91 and the reverse surface 92 face away from each other in the thickness direction z. The obverse surface 91 faces the first side in the thickness direction z, and the reverse surface 92 faces away from the obverse surface 91 (faces the second side in the thickness direction z). The reverse surface 92 of the heat-conducting member 9 is bonded to the obverse surface 511 of the element bonding portion 51 of the conductive member 5. The obverse surface 91 of the heat-conducting member 9 is exposed from the sealing resin 7.

Note that the heat-conducting member 9 is not limited to a DBC substrate. For example, the heat-conducting member 9 may be a direct plated copper (DPC) substrate, which consists of a ceramic plate with copper plating applied to both sides. The heat-conducting member 9 may be a plating layer made of copper, for example, or a thermal conductive material, such as a thermal interface material (TIM).

According to the present embodiment, the lead bonding portion 52 of the conductive member 5 is bonded in direct contact with the obverse surface 141 of the pad portion 14. Thus, similarly to the semiconductor device A10, the semiconductor device A30 ensures that the height of the conductive member 5 from the obverse surface 121 of the die pad 12 is controlled to be consistent. In addition, according to the present embodiment, the obverse surface 91 of the heat-conducting member 9 is exposed from the sealing resin 7. This allows the semiconductor device A30 to dissipate heat generated by the semiconductor element 2 through the obverse surface 91 of the heat-conducting member 9 via the conductive member 5. In addition, the semiconductor device A30 has a configuration in common with the semiconductor device A10, thereby achieving the same effect as the semiconductor device A10.

### Fourth Embodiment

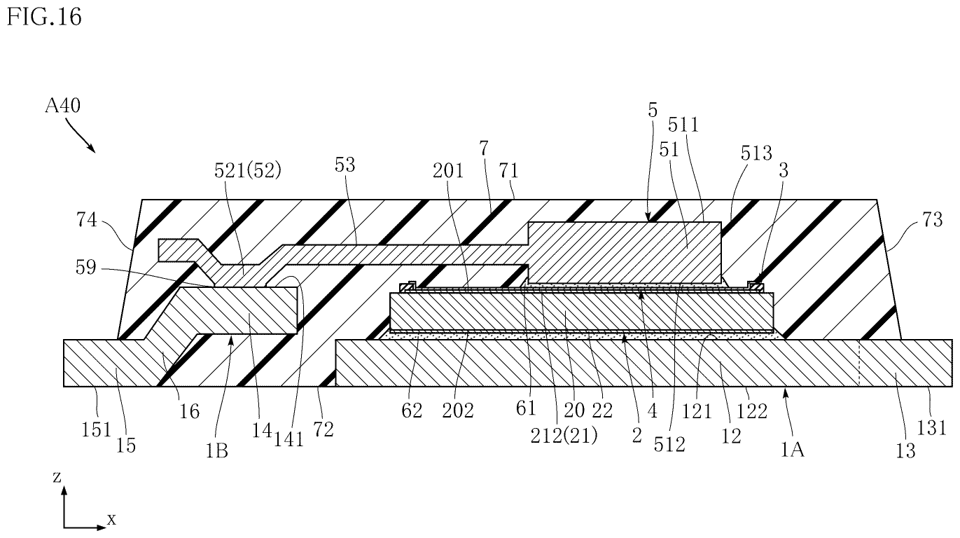

FIG. 16 is a view for illustrating a semiconductor device A40 according to a fourth embodiment of the present disclosure. FIG. 16 is a sectional view of the semiconductor device A40 and corresponds to FIG. 6. The semiconductor device A40 of the present embodiment differs from the first embodiment in that the conductive member 5 is covered with the sealing resin 7 and is not exposed from the resin obverse surface 71. Other than that, the configurations and operation of the present embodiment are similar to those of the first embodiment. Note that the present embodiment may be combined with any part of the first to third embodiments and the variations described above.

The semiconductor device A40 of the present embodiment includes the conductive member 5 that is entirely covered with the sealing resin 7. Hence, the obverse surface 511 of the element bonding portion 51 is not exposed from the resin obverse surface 71 of the sealing resin 7. In addition, the semiconductor device A40, unlike the semiconductor device A30, does not include the heat-conducting member 9.

According to the present embodiment, the lead bonding portion 52 of the conductive member 5 is bonded in direct contact with the obverse surface 141 of the pad portion 14. Thus, similarly to the semiconductor device A10, the semiconductor device A40 ensures that the height of the conductive member 5 from the obverse surface 121 of the die pad 12 is controlled to be consistent. In addition, the semiconductor device A40 has a configuration in common with the semiconductor device A10, thereby achieving the same effect as the semiconductor device A10.

### Fifth Embodiment

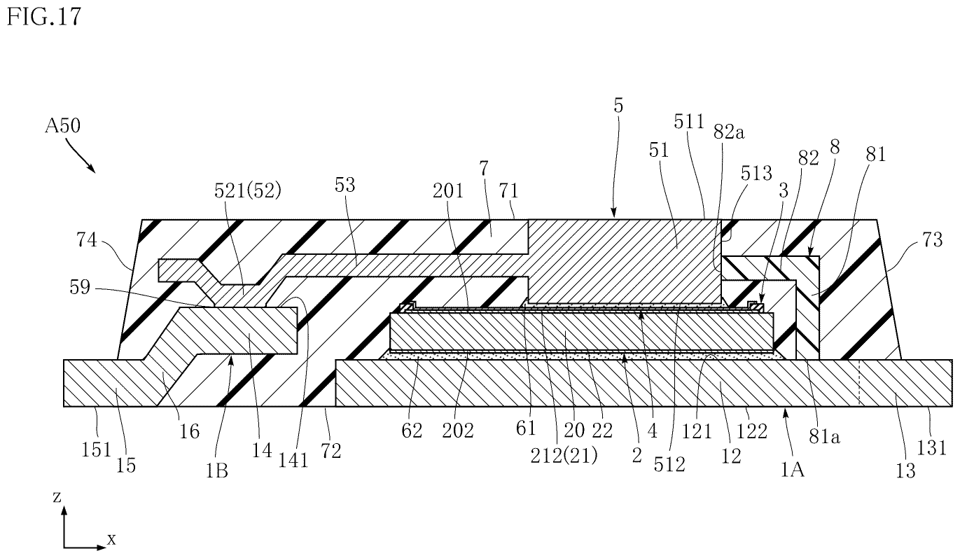

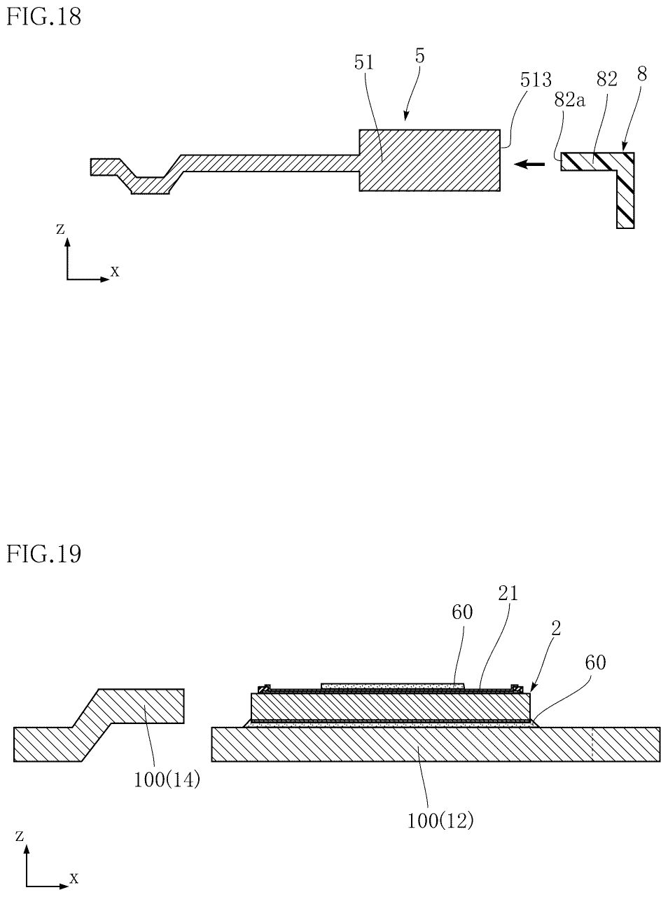

FIGS. 17 to 21 are views for illustrating a semiconductor device A50 according to a fifth embodiment of the present disclosure. FIG. 17 is a sectional view of the semiconductor device A50 and corresponds to FIG. 6. FIGS. 18 to 21 are sectional views each for illustrating a step of an example method for manufacturing the semiconductor device A50. The semiconductor device A50 of the present embodiment differs from the first embodiment in the addition of a positioning member 8 that determines the height of the conductive member 5 from the obverse surface 121 of the die pad 12. Other than that, the configurations and operation of the present embodiment are similar to those of the first embodiment. Note that the present embodiment may be combined with any part of the first to fourth embodiments and the variations described above.

The semiconductor device A50 of the present embodiment includes the positioning member 8. The positioning member 8 is made of an insulating material and is placed in contact with the conductive member 5 and the obverse surface 121 of the die pad 12. The positioning member 8 is made of a synthetic resin, for example. The type of synthetic resin is not specifically limited. The positioning member 8 is located on the opposite side of the semiconductor element 2 from the lead 1B in the first direction x.

As viewed in the second direction y, the positioning member 8 has an L shape and includes a first portion 81 and a second portion 82. The second portion 82 is formed with a plate extending in the first direction x, and its end surface 82a facing the second side in the first direction x is bonded in contact with the end surface 513 of the element bonding portion 51. The process for the bonding is not limited, and examples of the process include thermal compression bonding, which involves heating the positioning member 8 and the conductive member 5 and pressing them together to form the bond. Alternatively, the positioning member 8 may be formed in contact with the end surface 513 of the element bonding portion 51 by introducing molten resin material into a mold and then allowing it to harden.

The first portion 81 is a plate extending in the thickness direction z, and its end on the first side in the thickness direction z is connected to the end of the second portion 82 on the first side in the first direction x. The end surface 81a of the first portion 81 facing the second side in the thickness direction z is in contact with the obverse surface 121 of the die pad 12. As will be described later regarding the manufacturing method, the positioning member 8 and the conductive member 5 are first joined into a single unit. After that, the conductive member 5 is placed so that the end surface 81a of the first portion 81 is in contact with the obverse surface 121 of the die pad 12. Then, the lead bonding portion 52 is bonded to the pad portion 14, and the conductive bonding materials 61 and 62 are hardened. As a result, the end surface 81a of the first portion 81 is fixed in contact with the obverse surface 121 of the die pad 12.

The material of the positioning member 8 is not limited to synthetic resin, and other insulating materials are also usable. For example, the positioning member 8 may be made of a ceramic material. Additionally, the shape and position of the positioning member 8 are not specifically limited either. The semiconductor device A50 may include a plurality of positioning members 8. In such a case, the arrangement of the positioning members 8 is not specifically limited.

The following describes a method for manufacturing the semiconductor device A50, with reference to FIGS. 18 to 21. FIGS. 18 to 21 are sectional views corresponding to FIG. 6, each illustrating a step of a method for manufacturing the semiconductor device A50.

First, a conductive member 5 and a positioning member 8 are prepared as shown in FIG. 18. For example, the positioning member 8 may be formed by injection molding using a mold. Note, however, that the process for forming the positioning member 8 is not specifically limited.

Subsequently, as shown in FIG. 18, the positioning member 8 is joined to conductive member 5 by thermal compression bonding. Specifically, the positioning member 8 and the conductive member 5 are heated to an appropriate temperature. Then, a pressure is applied to bring the end surface 82a into intimate contact with the end surface 513. This causes the positioning member 8 to undergo plastic deformation to form the bond. Through this process, the positioning member 8 and the conductive member 5 are joined into a single unit. Alternatively, the positioning member 8 may be formed in contact with the end surface 513 of the conductive member 5 by placing the conductive member 5 in a mold, introducing molten resin material into the mold, and then allowing it to harden.

Subsequently, as in the first embodiment, the lead frame 100 and the semiconductor element 2 are prepared, solder paste 60 is applied to the obverse surface 101 of the lead frame 100 to cover the portion for forming the obverse surface 121 of the die pad 12, and the semiconductor element 2 is placed on the applied solder paste 60 (see FIG. 10). Subsequently, as shown in FIG. 19, the solder paste 60 is applied to the first electrode 21 of the semiconductor element 2.

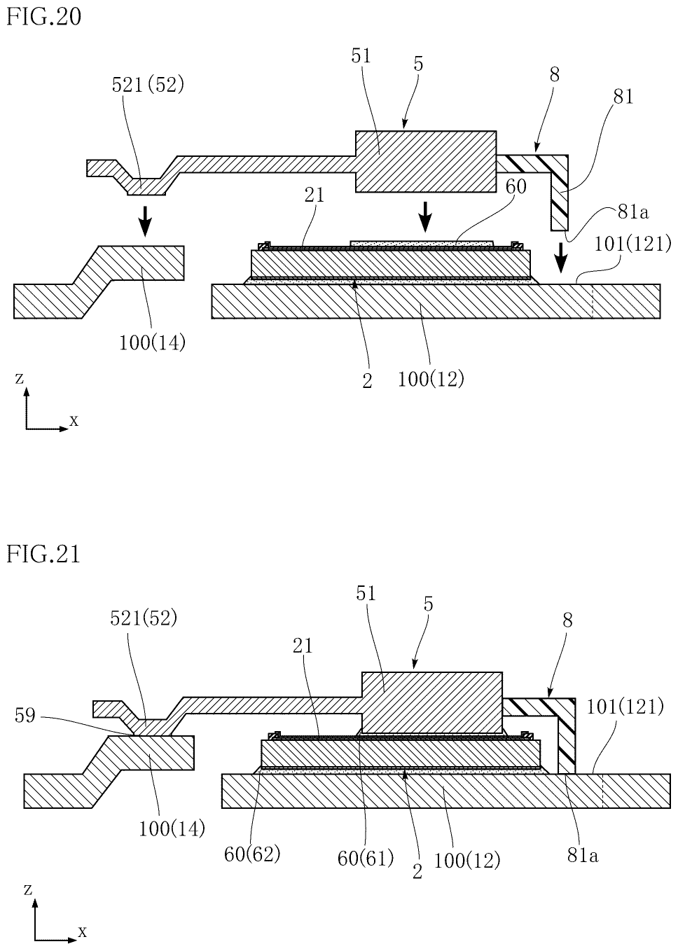

Subsequently, as shown in FIG. 20, the conductive member 5 is placed to span across the semiconductor element 2 and the portion of the lead frame 100 that is for forming the pad portion 14. In this state, the element bonding portion 51 is placed on the solder paste 60, whereas the protruding portion 521 of the lead bonding portion 52 is placed directly on the portion of the lead frame 100 that is for forming the pad portion 14. In addition, the conductive member 5 is placed such that the end surface 81a of the positioning member 8, which has been integrated with the conductive member 5, is in contact with the portion of the obverse surface 101 of the lead frame 100 that is for forming the obverse surface 121 of the die pad 12.

Subsequently, the protruding portion 521 of the lead bonding portion 52 is joined to the portion of the lead frame 100 that is for forming the pad portion 14 by ultrasonic bonding. As a result, a solid-state bonding interface 59 forms between the protruding portion 521 and the portion for forming the pad portion 14 as shown in FIG. 21. The subsequent steps are the same as those of the first embodiment.

According to the present embodiment, the lead bonding portion 52 of the conductive member 5 is bonded in direct contact with the obverse surface 141 of the pad portion 14. Thus, similarly to the semiconductor device A10, the semiconductor device A50 ensures that the height of the conductive member 5 from the obverse surface 121 of the die pad 12 is controlled to be consistent. In addition, the semiconductor device A50 has a configuration in common with the semiconductor device A10, thereby achieving the same effect as the semiconductor device A10.

Additionally, the semiconductor device A50 of the present embodiment includes the positioning member 8. The positioning member 8 is integrated with the conductive member 5 by bonding the end surface 82a of the second portion 82 directly to the end surface 513 of the element bonding portion 51. The conductive member 5 is secured in the state where the end surface 81a of the positioning member 8, which has been integrated with the conductive member 5, is in contact with the obverse surface 121 of the die pad 12. Thus, the height (the position in the thickness direction z) of the conductive member 5 from the obverse surface 121 is determined also by the dimension of the positioning member 8 in the thickness direction z. This configuration ensures that the height of the element bonding portion 51 is more accurately determined than a configuration without the positioning member 8. The semiconductor device A50 thus provides more precise control over the height of the conductive member 5 from the obverse surface 121.

According to the present embodiment, in addition, the positioning member 8 includes the first portion 81 extending in the thickness direction z, and the second portion 82 extending in the first direction x. This allows the positioning member 8 to be in contact with the end surface 513 of the element bonding portion 51 at the end surface 82a of the second portion 82 and with the obverse surface 121 of the die pad 12 at the end surface 81a of the first portion 81.

According to the present embodiment, in addition, the positioning member 8 is located on the opposite side of the semiconductor element 2 from the lead 1B in the first direction x. The lead bonding portion 52 of the conductive member 5 is bonded to the pad portion 14 of the lead 1B. That is, the height of the conductive member 5 is determined on the first side of the semiconductor element 2 in the first direction x by the positioning member 8, and on the second side of the semiconductor element 2 in the first direction x by the height of the obverse surface 141 of the pad portion 14. In other words, the height of the semiconductor device A50 is determined on both sides of the semiconductor element 2 in the first direction x, ensuring more accurate control of the height of the conductive member 5 compared to configurations with the positioning member 8 placed differently.

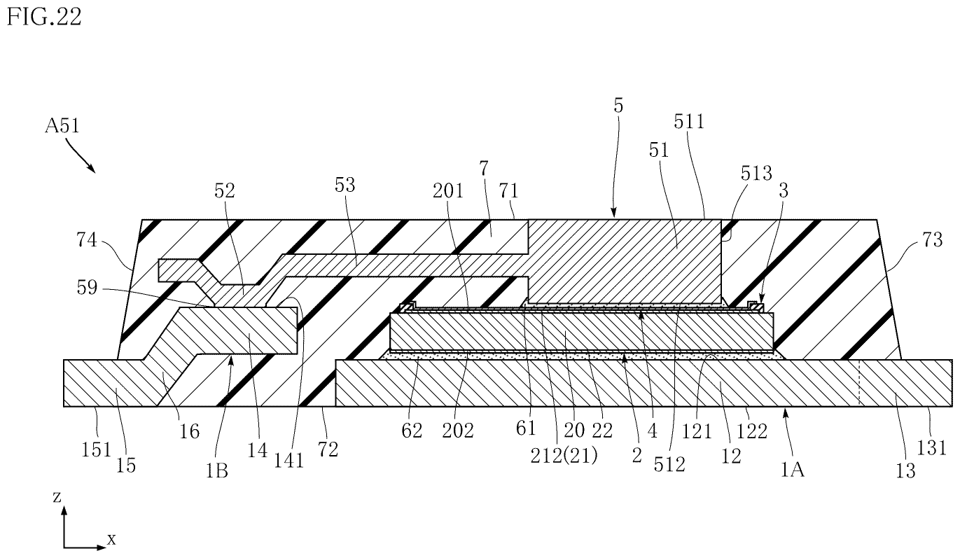

FIGS. 22 to 26 show variations of the semiconductor device A50 according to the fifth embodiment. In these figures, elements that are identical or similar to those of the embodiment described above are indicated by the same reference numerals, and redundant descriptions are omitted.

### First Variation of Fifth Embodiment:

FIG. 22 depicts a semiconductor device A51 according to a first variation of the fifth embodiment. FIG. 22 is a sectional view of the semiconductor device A51 and corresponds to FIG. 6. The semiconductor device A51 of the present variation does not include the positioning member 8. In this variation, the positioning member 8 is removed during the manufacture of the semiconductor device A51. Thus, the semiconductor device A51 is identical in configuration to the semiconductor device A10 according to the first embodiment. The method for manufacturing the semiconductor device A51 is identical to that for the semiconductor device A50 of the fifth embodiment, from the reflowing step to the step of solidifying the solder paste 60. The method for manufacturing the semiconductor device A51 includes, as a subsequent step, removing the positioning member 8 before the step of bonding wire 65. In the present embodiment, the positioning member 8 is made of a thermoplastic resin. Examples of the thermoplastic resin include polyethylene and polypropylene. The step of removing the positioning member 8 involves dissolving the positioning member 8 with an organic solvent. Alternatively, the positioning member 8 may be removed by other methods.

According to this variation, the semiconductor device A51 includes the positioning member 8 when the conductive member 5 is bonded to the first electrode 21 and the pad portion 14. Similarly to the semiconductor device A50, the semiconductor device A51 therefore ensures precise control over the height of the conductive member 5 from the obverse surface 121. According to the variation, however, the finished semiconductor device A51 does not include the positioning member 8. Thus, the semiconductor device A51 is without the possibility of any gaps between the positioning member 8 and the sealing resin 7. Consequently, the semiconductor device A51 eliminates the risk of cracks originating from such a gap between the positioning member 8 and the sealing resin 7.

Although the positioning member 8 in this variation has been described as being made of thermoplastic resin, this is not a limitation. The positioning member 8 may be made of a water soluble resin. Examples of the water soluble resin include polyethylene oxide, polyvinyl alcohol, resol-type phenolic resin, methylolated urea resin, methylolated melamine resin, polyacrylamide, and carboxymethyl cellulose. In this case, the step of removing the positioning member 8 involves dissolving the positioning member 8 with water.

### Second Variation of Fifth Embodiment:

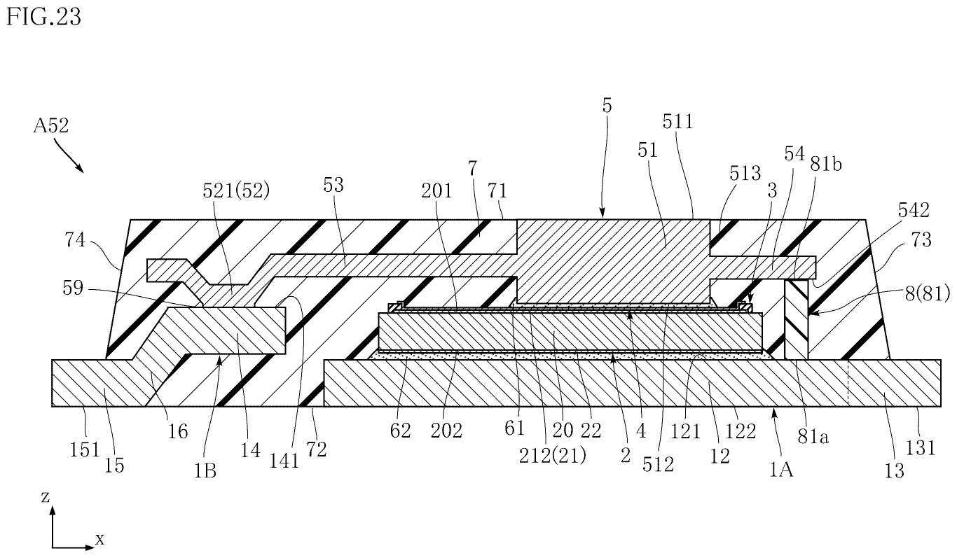

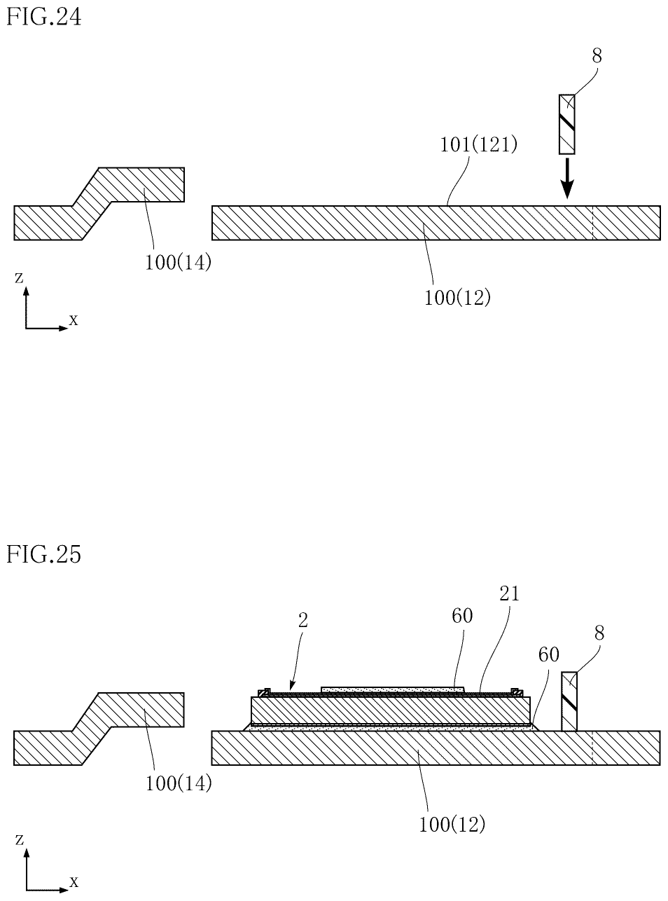

FIGS. 23 to 26 are views for illustrating a semiconductor device A52 according to a second variation of the fifth embodiment. FIG. 23 is a sectional view of the semiconductor device A52 and corresponds to FIG. 6. FIGS. 24 to 26 are sectional views each illustrating a step of an example method for manufacturing the semiconductor device A52. The semiconductor device A52 differs from the semiconductor device A50 in the shapes of the positioning member 8 and the conductive member 5.

According to the present variation, the conductive member 5 additionally includes a protruding portion 54. The protruding portion 54 protrudes from the end surface 513 of the element bonding portion 51 toward the first side in the first direction x. The protruding portion 54 has a second reverse surface 542 facing the same side as the reverse surface 512 in the thickness direction z (the second side in the thickness direction z).

The positioning member 8 of the present variation does not include the second portion 82 and composed only of the first portion 81 that is a plate extending in the thickness direction z. The positioning member 8 is bonded to the obverse surface 121 of the die pad 12 at the end surface 81a facing the second side in the thickness direction z. The process for the bonding is not limited, and examples of the process include thermal compression bonding, which involves heating the positioning member 8 and the die pad 12 (the lead frame 100) and pressing them together to form the bond. Alternatively, the positioning member 8 may be formed in contact with the obverse surface 121 of the die pad 12 by introducing molten resin material into a mold and then allowing it to harden. The positioning member 8 is also in contact with the second reverse surface 542 of the protruding portion 54 of the conductive member 5 at the end surface 81b facing the first side in the thickness direction z. In other words, the positioning member 8 is in contact with the obverse surface 121 of the die pad 12 and the second reverse surface 542 of the conductive member 5.

The following describes the example method for manufacturing the semiconductor device A52, with reference to FIGS. 24 to 26. FIGS. 24 to 26 are sectional views each illustrating a step of the method for manufacturing the semiconductor device A52 and correspond to FIG. 6.

First, a lead frame 100 and a positioning member 8 are prepared as shown in FIG. 24. Subsequently, as shown in FIG. 24, the positioning member 8 is joined by thermal compression bonding to the portion of the obverse surface 101 of the lead frame 100 that is for forming the obverse surface 121 of the die pad 12. As a result, the positioning member 8 and the die pad 12 (the lead frame 100) are joined together into a single unit. Alternatively, the positioning member 8 may be formed in contact with the obverse surface 101 of the lead frame 100 by placing the lead frame 100 into a mold, introducing molten resin material into the mold, and then allowing it to harden. In a separate step, the conductive member 5 and the semiconductor element 2 are prepared.

Subsequently, solder paste 60 is applied to the obverse surface 101 of the lead frame 100 to cover the portion for forming the obverse surface 121 of the die pad 12, and the semiconductor element 2 is placed on the applied solder paste 60. Subsequently, as shown in FIG. 25, the solder paste 60 is applied to the first electrode 21 of the semiconductor element 2.

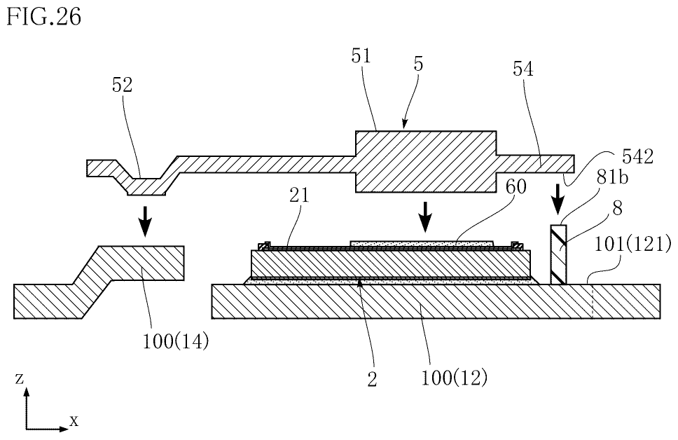

Subsequently, as shown in FIG. 26, the conductive member 5 is placed to span across the semiconductor element 2 and the portion of the lead frame 100 that is for forming the pad portion 14. In this state, the element bonding portion 51 is placed on the solder paste 60, whereas the protruding portion 521 of the lead bonding portion 52 is placed directly on the portion of the lead frame 100 that is for forming the pad portion 14. The conductive member 5 is placed such that the second reverse surface 542 of the protruding portion 54 is in contact with the end surface 81b of the positioning member 8, which has been integrated with the lead frame 100. The subsequent steps are the same as those for the method for manufacturing the semiconductor device A50 according to the fifth embodiment.

According to the present variation, the semiconductor device A52 includes the positioning member 8. The positioning member 8 is integrated with the die pad 12 by bonding the end surface 81a directly to the obverse surface 121 of the die pad 12. The conductive member 5 is secured in the state where the second reverse surface 542 of the protruding portion 54 is in contact with the end surface 81b of the positioning member 8, which is integral with the die pad 12 (the lead frame 100). Thus, the height (the position in the thickness direction z) of the conductive member 5 from the obverse surface 121 is determined by the dimension of the positioning member 8 in the thickness direction z. Similarly to the semiconductor device A50, the semiconductor device A52 of the present variation therefore ensures precise control over the height of the conductive member 5 from the obverse surface 121. According to the present variation, in addition, the positioning member 8 extends in the thickness direction z. Thus, the positioning member 8 is placed such that the end surface 81b is in contact with the second reverse surface 542 of the protruding portion 54, and that the end surface 81a is in contact with the obverse surface 121 of the die pad 12.

Although the present variation described above is an example in which the positioning member 8 is joined to the die pad 12 first. However, this is not a limitation. For instance, it is possible to join the end surface 81b of the positioning member 8 to the second reverse surface 542 of the protruding portion 54 before the positioning member 8 is joined to the conductive member 5. It is also possible that the conductive member 5 does not include the protruding portion 54. Instead, the element bonding portion 51 has a portion extending beyond the first side of the semiconductor element 2 in the first direction, and its the reverse surface 512 is in contact with the positioning member 8.

The semiconductor devices and methods for manufacturing semiconductor devices are not limited to those described above in the embodiments. Various modifications in design may be made freely in the specific structure of each part of the semiconductor devices and the steps of the method for manufacturing semiconductor devices according to the present disclosure.

The present disclosure includes embodiments described in the following clauses.

### Clause 1.

A semiconductor device (A1) comprising:
a first lead (1A) including a die pad (12) that includes a die-pad obverse surface (121) facing a first side in a thickness direction (z);
a semiconductor element (2) including an element obverse surface (201) facing the first side in the thickness direction, and a first electrode (21) disposed on the element obverse surface, the semiconductor element being mounted on the die-pad obverse surface;
a second lead (1B) including a second obverse surface (141) facing the first side in the thickness direction, the second lead being spaced apart from the first lead in a first direction (x) perpendicular to the thickness direction;
a conductive member (5) electrically bonded to the first electrode and the second obverse surface; and
a sealing resin (7) covering the semiconductor element,
wherein the conductive member is in direct contact with the second lead.

### Clause 2.

The semiconductor device according to Clause 1, wherein a solid-state bonding interface (59) is present between the conductive member and the second lead.

### Clause 3. (Second Embodiment, FIG. 14)

The semiconductor device according to Clause 1, wherein the conductive member includes a welding mark (523) that extends to an interior of the second lead.

### Clause 4.

The semiconductor device according to any one of Clauses 1 to 3, wherein the conductive member and the second lead are made of a same constituent material.

### Clause 5.

The semiconductor device according to any one of Clauses 1 to 4, wherein a constituent material of the conductive member and the second lead contains Cu.

### Clause 6.

The semiconductor device according to any one of Clauses 1 to 5, wherein the second lead includes a pad portion (14) covered with the sealing resin, and a terminal portion (15) including a portion exposed from the sealing resin, and
the second obverse surface is located in the pad portion.

### Clause 7.

The semiconductor device according to any one of Clauses 1 to 6, wherein the conductive member includes a conductive-member obverse surface (511) facing the first side in the thickness direction, and
the conductive-member obverse surface is exposed from the sealing resin.

### Clause 8. (Third Embodiment, FIG. 15)

The semiconductor device according to any one of Clauses 1 to 6, further comprising a heat-conducting member (9) bonded to the conductive member,
wherein the conductive member includes a conductive-member obverse surface facing the first side in the thickness direction, and
the heat-conducting member is bonded to the conductive-member obverse surface and is exposed from the sealing resin.

### Clause 9.

The semiconductor device according to any one of Clauses 1 to 8, wherein the die pad further includes a die-pad reverse surface (122) facing a second side in the thickness direction, and
the die-pad reverse surface is exposed from the sealing resin.

### Clause 10. (Fifth Embodiment, FIGS. 17 to 26)

The semiconductor device according to any one of Clauses 1 to 9, further comprising a positioning member (8) containing an insulating material and in contact with the conductive member and the die-pad obverse surface.

### Clause 11. (Fifth Embodiment, FIG. 17)

The semiconductor device according to Clause 10, wherein the conductive member includes a conductive-member end surface (513) facing a first side in the first direction, and
the positioning member includes a first portion (81) and a second portion (82), the first portion being in contact with the die-pad obverse surface and extending in the thickness direction, the second portion being in contact with the conductive-member end surface and extending in the first direction.

### Clause 12. (Second Variation of Fifth Embodiment, FIG. 23)

The semiconductor device according to Clause 10, wherein the conductive member includes a conductive-member reverse surface (542) facing a second side in the thickness direction, and
the positioning member is in contact with the die-pad obverse surface and the conductive-member reverse surface and extends in the thickness direction.

### Clause 13. (FIGS. 10 to 12)

A method for manufacturing a semiconductor device, the method comprising:
placing a semiconductor element on a first bonding member (60) located on a die-pad obverse surface of a die pad;
placing a second bonding member (60) on a first electrode of the semiconductor element;
placing a conductive member to span across the semiconductor element and a second lead that is spaced apart from the die pad;
bonding the conductive member and the second lead in direct contact with each other; and
heating to solidify the first bonding member and the second bonding member.

### Clause 14.

The method according to Clause 13, wherein the bonding involves bonding the conductive member and the second lead by ultrasonic bonding.

### Clause 15.

The method according to Clause 13, wherein the bonding involves bonding the conductive member and the second lead by laser welding.

### REFERENCE NUMERALS

A10 to A11, A20, A30, A40, A50 to A52: semiconductor device
1A, 1B, 1C: lead 12: die pad 121: obverse surface 122: reverse surface
13: first terminal portion 131: reverse-surface mounting portion
14: pad portion 141: obverse surface 142: plating layer 15: second terminal portion
151: reverse-surface mounting portion 16: bent portion 17: pad portion
18: second terminal portion 181: reverse-surface mounting portion 19: bent portion
2: semiconductor element 20: element body 201: element obverse surface
202: element reverse surface 21: first electrode 212: first-electrode pad portion
22: second electrode
5: conductive member
23: third electrode 3: insulating part 4: metal laminate
51: element bonding portion 511: obverse surface
512: reverse surface 513: end surface 52: lead bonding portion
521: protruding portion 521a: contact surface 522: plating layer 523: welding mark
53: intermediate portion 54: protruding portion 542: second reverse surface
59: solid-state bonding interface 61, 62: conductive bonding material 65: wire
7: sealing resin 71: resin obverse surface 72: resin reverse surface
73, 74, 75, 76: resin side surface 8: positioning member 81: first portion
81a, 81b: end surface 82: second portion 82a: end surface
9: heat-conducting member 91: obverse surface 92: reverse surface
9a: insulating plate 9b: metal layer 100: lead frame
101: obverse surface 60: solder paste

1. A semiconductor device comprising:
a first lead including a die pad that includes a die-pad obverse surface facing a first side in a thickness direction;
a semiconductor element including an element obverse surface facing the first side in the thickness direction, and a first electrode disposed on the element obverse surface, the semiconductor element being mounted on the die-pad obverse surface;
a second lead including a second obverse surface facing the first side in the thickness direction, the second lead being spaced apart from the first lead in a first direction perpendicular to the thickness direction;
a conductive member electrically bonded to the first electrode and the second obverse surface; and
a sealing resin covering the semiconductor element,
wherein the conductive member is in direct contact with the second lead.

2. The semiconductor device according to claim 1, wherein a solid-state bonding interface is present between the conductive member and the second lead.

3. The semiconductor device according to claim 1, wherein the conductive member includes a welding mark that extends to an interior of the second lead.

4. The semiconductor device according to claim 1, wherein the conductive member and the second lead are made of a same constituent material.

5. The semiconductor device according to claim 1, wherein a constituent material of the conductive member and the second lead contains Cu.

6. The semiconductor device according to claim 1, wherein the second lead includes a pad portion covered with the sealing resin, and a terminal portion including a portion exposed from the sealing resin, and
the second obverse surface is located in the pad portion.

7. The semiconductor device according to claim 1, wherein the conductive member includes a conductive-member obverse surface facing the first side in the thickness direction, and
the conductive-member obverse surface is exposed from the sealing resin.

8. The semiconductor device according to claim 1, further comprising a heat-conducting member bonded to the conductive member,
wherein the conductive member includes a conductive-member obverse surface facing the first side in the thickness direction, and
the heat-conducting member is bonded to the conductive-member obverse surface and is exposed from the sealing resin.

9. The semiconductor device according to claim 1, wherein the die pad further includes a die-pad reverse surface facing a second side in the thickness direction, and
the die-pad reverse surface is exposed from the sealing resin.

10. The semiconductor device according to claim 1, further comprising a positioning member containing an insulating material and in contact with the conductive member and the die-pad obverse surface.

11. The semiconductor device according to claim 10, wherein the conductive member includes a conductive-member end surface facing a first side in the first direction, and
the positioning member includes a first portion and a second portion, the first portion being in contact with the die-pad obverse surface and extending in the thickness direction, the second portion being in contact with the conductive-member end surface and extending in the first direction.

12. The semiconductor device according to claim 10, wherein the conductive member includes a conductive-member reverse surface facing a second side in the thickness direction, and
the positioning member is in contact with the die-pad obverse surface and the conductive-member reverse surface and extends in the thickness direction.

13. A method for manufacturing a semiconductor device, the method comprising:
placing a semiconductor element on a first bonding member located on a die-pad obverse surface of a die pad;
placing a second bonding member on a first electrode of the semiconductor element;
placing a conductive member to span across the semiconductor element and a second lead that is spaced apart from the die pad;
bonding the conductive member and the second lead in direct contact with each other; and
heating to solidify the first bonding member and the second bonding member.

14. The method according to claim 13, wherein the bonding involves bonding the conductive member and the second lead by ultrasonic bonding.

15. The method according to claim 13, wherein the bonding involves bonding the conductive member and the second lead by laser welding.
